(19) United States
(12) Patent Application Publication
(10) Pub. No.: US 2025/0218837 A1
(43) Pub. Date: Jul. 3, 2025

(54) SYSTEM AND PROCESS FOR POST-CHEMICAL MECHANICAL POLISHING CLEANING

(71) Applicant: Applied Materials, Inc., Santa Clara, CA (US)

(72) Inventors: Clinton SAKATA, San Jose, CA (US); Brian K. KIRKPATRICK, Sunnyvale, CA (US)

(21) Appl. No.: 18/400,319

(22) Filed: Dec. 29, 2023

(51) Int. Cl. H01L 21/677; H01L 21/67; H01L 21/687

(52) U.S. Cl. CPC H01L 21/67742; H01L 21/67057; H01L 21/68707

(57) ABSTRACT

A substrate cleaning system to remove particulates from multiple substrates includes a cleaning tank for applying a cleaning liquid to substrates, a rinse tank for applying a rinsing liquid to substrates, and a robot system. The cleaning tank includes a stationary lid, an input lid, and an output lid. The input and output lids allow a substrate carrier designed to carry an individual substrate to access an inner volume of the cleaning tank for processing. A transport system moves the substrate in the substrate carrier through the inner volume of the cleaning tank by creating a series of gaps between substrates to allow proper processing. The robot system transports substrates through the input and output lids of the cleaning tank, and transports substrates into the rinse tank.

### CROSS-REFERENCE TO RELATED APPLICATIONS

This application is a continuation of U.S. application Ser. No. 18/150,869, filed Jan. 6, 2023, which is herein incorporated by reference.

### BACKGROUND

### Field

Embodiments of the presently disclosed subject matter generally relate to apparatus, system, and methods for in-line post polish cleaning of substrates, such as semiconductor substrates.

### Description of the Related Art

An integrated circuit is typically formed on a substrate (e.g., a semiconductor wafer) by the sequential deposition of conductive, semiconductive, or insulative layers on the substrate, and by the subsequent processing of the layers.

One fabrication step involves depositing a filler layer over a non-planar surface disposed on the substrate and planarizing the filler layer until the non-planar surface is exposed. For example, a conductive filler layer can be deposited on a patterned insulative layer disposed on the substrate to fill the trenches or holes in the insulative layer. The filler layer is then polished until the raised pattern of the insulative layer is exposed.

Chemical mechanical polishing (CMP) is one accepted method of planarization known in the art. This planarization method typically requires that the substrate be mounted on a carrier head. The exposed surface of the substrate is placed against a rotating polishing pad. The carrier head provides a controllable load on the substrate to push it against the polishing pad. For example, the carrier head may provide a specified pressure on the backside of the substrate to push it against the polishing pad. A polishing liquid, such as a slurry with abrasive particles, is supplied to the surface of the polishing pad. For example, cerium-based slurries, such as slurries containing cerium oxide, can be used in the polishing of a semiconductor or insulating thin layer in CMP.

The slurry of abrasive particles can include cerium oxide particulates and other additives which contribute to the polishing process. The benefits allow the substrates to be polished with stability without generating scratches. To remove these particulates, the substrates can be subjected to a cleaning process that can include the use of harsh oxidizing solvents. For example, a mixture of sulfuric acid and hydrogen peroxide (i.e., sulfuric peroxide mixture (SPM)) can be used in the removal or dissolution of cerium oxide particulates from the surfaces of a substrate after polishing. SPM cleaning can be performed in a parallel separated mode in which each substrate is placed in a bath in a separate tank. Typically, the SPM cleaning process is performed in a separate wet bench apparatus in which wafers are inbound in a dry state after the CMP polishing. It is performed to accommodate other methods of post-CMP cleaning when cerium oxide particulates are not sufficiently removed.

The substrates are generally processed through an SPM cleaning tank in batches. This method is not compatible with CMP polishing platforms based on single-wafer processing since the cleaning tank will require its lids to open over the frequency of the platform's throughput. When the lid of the SPM tank opens, steam and sulfuric vapors will escape causing a change in temperature, bath concentration, as well as increasing the risk of cross contamination of the process. In addition, each wafer will be exposed over different rates of its process which will pose additional control challenges.

Based on the above, there is a need for improvement in the method to allow the integration of an SPM process to work within a single-wafer processing platform for post-CMP cleaning.

### SUMMARY

Embodiments described herein generally relate to apparatus, systems, and methods for semiconductor processing. More particularly embodiments herein provide a post-chemical mechanical polishing cleaning system configured to process substrates individually and in batches.

In one embodiment, a system for cleaning a substrate is provided. The system includes an input tank, a cleaning tank, a rinse tank, an output tank, and a robot system including a plurality of robot arms configured to transfer a substrate carrier between the input tank, the cleaning tank, the rinse tank, and the output tank. The cleaning tank is configured to contain a cleaning fluid for applying to the substrate. The cleaning tank includes a top surface and an outer surface adjacent to the top surface. The top surface and the outer surface define an inner volume. The outer surface includes an upper portion and a lower portion. The cleaning tank further includes a transport system connected to the upper portion of the cleaning tank, the lower portion of the cleaning tank, or a combination thereof. The transport system is configured to transport the substrate carrier containing the substrate. The cleaning tank further includes a stationary lid covering a majority of the top surface of the cleaning tank, at least one input lid assembly adjacent to a first side of the stationary lid, and at least one output lid assembly adjacent to a second side of the stationary lid. The at least one input lid assembly, the stationary lid, and the at least one output lid assembly cover an entirety of the top surface.

In another embodiment, a substrate carrier is provided. In this embodiment, the substrate carrier includes a carrier body, at least one lift handle feature incorporated in an upper portion of the carrier body, a substrate holder at a bottom inner surface of the carrier body configured to hold a substrate, and a protrusion extending from an outer surface of the carrier body. The substrate carrier is further configured to be transported by a transport system in a post-CMP cleaning system.

In yet another embodiment, a system for cleaning a substrate after chemical mechanical polishing is provided. In this embodiment, the system includes an input tank, a cleaning tank including a transport system, a substrate carrier, a rinse tank, an output tank, one or more wet robots, a substrate carrier robot system, and a controller. The controller is configured to insert the substrate into a substrate carrier in the input tank using the one or more wet robots, transfer the substrate carrier from the input tank to the cleaning tank using the substrate carrier robot system, transport the substrate in the substrate carrier through the cleaning tank for a predetermined period using the transport system, remove the substrate carrier from the cleaning tank using the substrate carrier robot system, insert the substrate carrier into the rinse tank using the substrate carrier robot system, rinse the substrate in the substrate carrier in the rinse tank, remove the substrate carrier from the rinse tank using the substrate carrier robot system, place the substrate carrier into the output tank using the substrate carrier robot system, and remove the substrate from the substrate carrier using the substrate carrier robot system.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIGS. 1A-1B are schematic top views of a chemical mechanical polishing (CMP) system according to embodiments discussed herein.

FIG. 2 is a schematic side view of a sulfuric peroxide mixture (SPM) module of the CMP system of FIG. 1 according to embodiments discussed herein.

FIG. 3 is a schematic front view of a portion of the SPM module of FIG. 2 according to embodiments discussed herein.

FIGS. 4A-4F are schematic diagrams of a walking beam system according to embodiments discussed herein.

FIGS. 5A-5F are schematic diagrams of a running beam system according to embodiments discussed herein.

FIG. 6 is a schematic diagram of a conveyor system according to embodiments discussed herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Sulfuric peroxide mixture (SPM) cleaning can be performed in a parallel separated mode in which each substrate is placed in a bath in a separate processing chamber, or tank. Although this permits parallel processing of multiple substrates, the use of separate tanks can increase the use of the processing chemistry, e.g., the sulfuric acid and hydrogen peroxide. Further, the chemistry may not be reusable, i.e., new chemistry may be needed for each substrate. This chemistry can be a significant expense.

Moreover, the time required for SPM processing can be fairly large relative to the polishing time, e.g., by a factor of 10 or more. Thus, in order to match the throughput of the polishing system so that SPM process is not gating the throughput, a large number of substrates would need to be processed in parallel by SPM. However, including multiple SPM tanks with each chamber processing a single substrate might not be feasible, due to cost, available footprint in the clean room, or chemistry expense.

An SPM cleaning tank may also have a large lid substantially spanning the length of the tank that opens to allow substrates to enter that tank. When the lid of the SPM cleaning tank opens, heated SPM vapor is released which changes the concentration of the SPM, lowers the temperature of the SPM, and corrodes equipment external to the cleaning tank. In addition, the risk of cross-contamination increases when the lid is opened and exposing the contents of the cleaning tank.

An approach that addresses one or more of these issues includes an SPM processing system in which multiple substrates are processed in the same tank while sharing and maintaining the chemistry of the SPM.

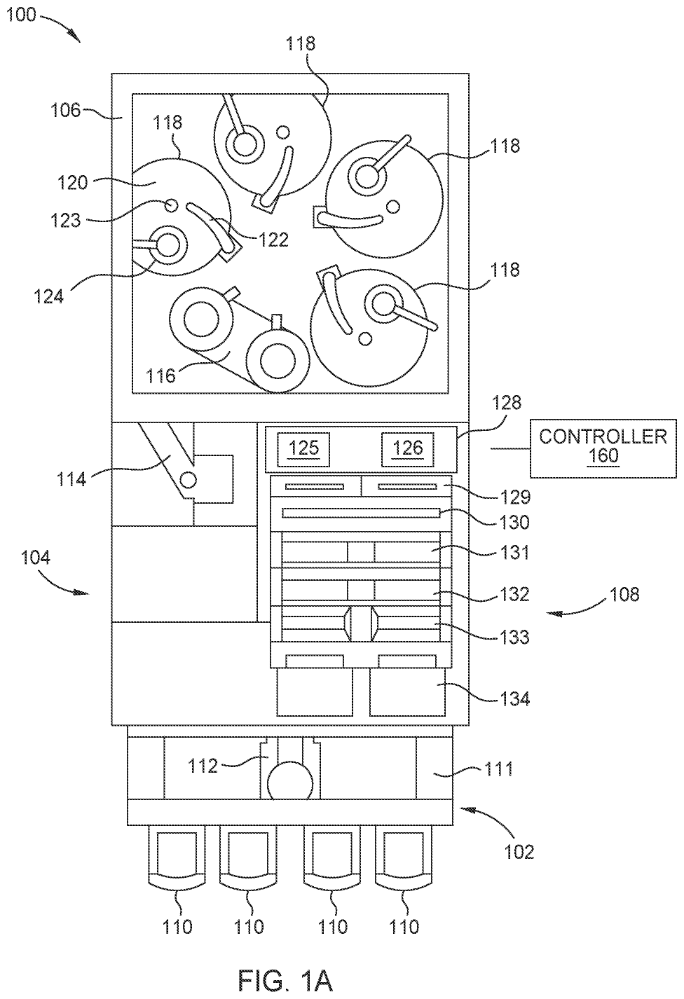

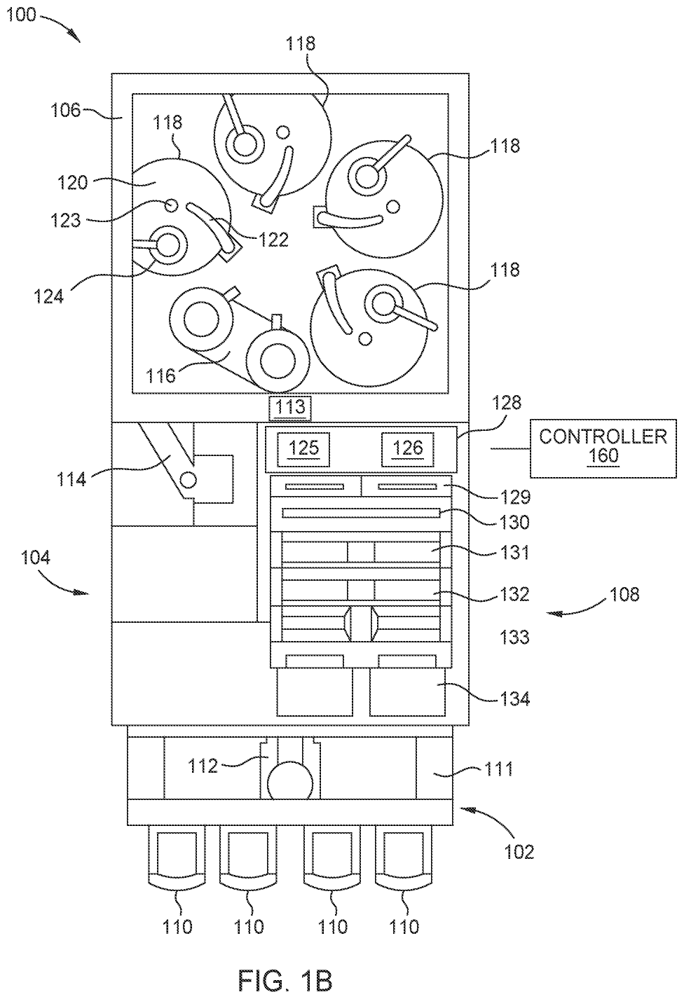

FIG. 1A illustrates a schematic top view of a chemical mechanical polishing (CMP) system 100. The CMP system 100 generally includes a factory interface module 102, an input module 104, a polishing module 106, and a cleaning module 108. These four major components are generally disposed within the CMP system 100.

The factory interface module 102 includes a support to hold a plurality of cassettes 110, a housing 111 that encloses a chamber, and one or more interface robots 112. The interface robot 112 generally provides the range of motion required to transfer substrates between the cassettes 110 and one or more of the other modules of the CMP system 100.

Unprocessed substrates are generally transferred from the cassettes 110 to the input module 104 by the interface robot 112. The input module 104 generally facilitates transfer of a substrate between the interface robot 112 and a transfer robot 114. The transfer robot 114 transfers the substrate between the input module 104 and the polishing module 106.

The polishing module 106 generally comprises a transfer station 116, and one or more polishing stations 118. The transfer station 116 is disposed within the polishing module 106 and is configured to accept the substrate from the transfer robot 114. The transfer station 116 transfers the substrate to at least one carrier head 124 of a polishing station 118 that retains the substrate during polishing.

The polishing stations 118 each includes a rotatable disk-shaped platen on which a polishing pad 120 is situated. The platen is operable to rotate about an axis. The polishing pad 120 can be a two-layer polishing pad with an outer polishing layer and a softer backing layer. The polishing stations 118 each further includes a dispensing arm 122, to dispense a polishing liquid, e.g., an abrasive slurry, onto the polishing pad 120. In the abrasive slurry, the abrasive particles can be silicon oxide, but some polishing processes use cerium oxide abrasive particles. Each polishing station 118 can also include a conditioner head 123 to maintain the polishing pad 120 at a consistent surface roughness.

The polishing stations 118 each includes at least one carrier head 124. The at least one carrier head 124 is operable to hold a substrate against the polishing pad 120 during a polishing operation. Following the polishing operation performed on a substrate, the at least one carrier head 124 transfers the substrate back to the transfer station 116.

The transfer robot 114 then removes the substrate from the polishing module 106 through an opening connecting the polishing module 106 with the remainder of the CMP system 100. The transfer robot 114 removes the substrate in a horizontal orientation from the polishing module 106 and transfers the substrate to the cleaning module 108.

The cleaning module 108 generally includes one or more cleaning devices that can operate independently or in concert. For example, the cleaning module 108 can include, from top to bottom in FIG. 1, an SPM module 128 (described further below), an input module 129, one or more brush or buffing pad cleaners 131, 132, a megasonic cleaner 133, and a drying module 134. Other possible cleaning devices include chemical spin cleaners and jet spray cleaners (not shown). A transport system, e.g., an overhead conveyor 130 that supports robot arms, can walk or run the substrate from cleaning device to cleaning device. Additionally, overhead transfer robots can be used for this same transport of substrates. Briefly, the one or more brush or buffing pad cleaners 131, 132 are devices in which the substrate can be placed and the surfaces of the substrate are contacted with rotating brushes or spinning buffing pads to remove any remaining particulates. The substrate is then transferred to the megasonic cleaner 133 in which high frequency vibrations produce controlled cavitation in a cleaning liquid to clean the substrate. Alternatively, the megasonic cleaner 133 can be positioned before the brush or buffing pad cleaners 131, 132. A final rinse can be performed in a rinsing module before being transferred to the drying module 134.

Although FIG. 1A illustrates the SPM module 128 as the first cleaning device in the sequence, this is not necessary for actual physical position or order of cleaning operations (although having the cleaning devices in same physical order as the order of operations will be more efficient for throughput). For example, the substrate could be processed by a brush or buffing pad cleaner 131 (e.g., a buff pad), then by the SPM module 128, then by another brush or buffing pad cleaner 132 (e.g., a rotating brush), and then by a jet spray cleaner (not shown). Additionally, as shown in FIG. 1B, there may be a horizontal pre-clean module 113 before the SPM module 128 in the sequence where the substrate may undergo an initial cleaning process before processing in the SPM module 128.

As described above, the CMP system 100 transfers the substrates from the polishing module 106 into the cleaning module 108. Debris from the polishing process, e.g., abrasive particles or organic materials from the polishing pad or slurry, can be stuck to the substrates. Some of these materials, e.g., cerium oxide particulates, and organic additives from the polishing module 106, are difficult to remove with the cleaners 131, 132, 133 listed above. Therefore, the substrates are moved to the in-line SPM module 128 within the cleaning module 108. The SPM module 128 shown in FIGS. 1A and 1B allows for the in-line SPM cleaning of a number of substrates concurrently. The SPM module 128 includes at least two tanks, i.e., a cleaning tank 125 and a hot/cold rinse tank 126. The hot/cold rinse tank 126 may include a plurality of tanks and may be configured for rinsing substrates (e.g., a quick dump rinse, overflow rinse, and/or spin/spray rinse).

In some embodiments, the SPM module 128 includes a separate input station, the cleaning tank 125, the hot/cold rinse tank 126, and a separate output station to properly isolate the SPM environment from the other areas of the cleaning module 108. FIGS. 1A and 1B show the cleaning tank 125 and the hot/cold rinse tank 126 positioned adjacent to each other, but the tanks can be disposed anywhere in the CMP system 100 in any manner that benefits the process

The CMP system 100 includes a controller 160 generally includes one or more processors, memory, and support circuits. The one or more processors may include a central processing unit (CPU) and may be one of any form of a general purpose processor that can be used in an industrial setting. The memory, or non-transitory computer-readable medium, is accessible by the one or more processors and may be one or more of memory such as random access memory (RAM), read only memory (ROM), floppy disk, hard disk, or any other form of digital storage, local or remote. The support circuits are coupled to the one or more processors and may comprise cache, clock circuits, input/output subsystems, power supplies, and the like. The various methods disclosed herein may generally be implemented under the control of the one or more processors by the one or more processors executing computer instruction code stored in the memory as, for example, a software routine. When the computer instruction code is executed by the one or more processors, the one or more processors controls the CMP system 100 to perform processes in accordance with the various methods disclosed herein.

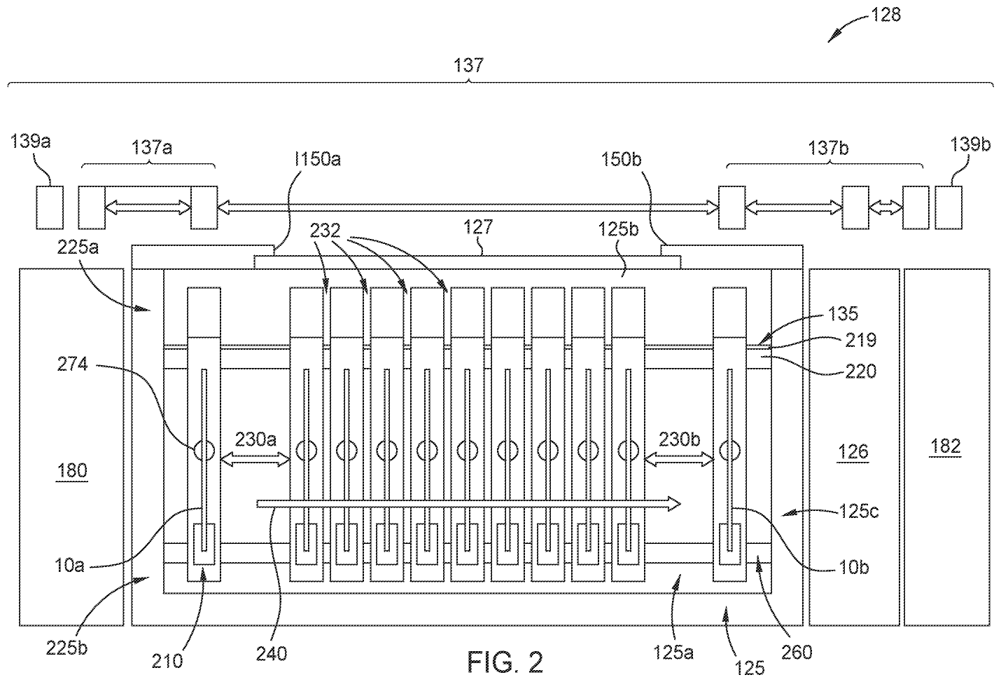

FIG. 2 illustrates a schematic side view of the SPM module 128. The SPM module 128 includes the cleaning tank 125 and a robot system 137 including one or more dedicated robot arms 137a, 137b to transfer the substrates within the SPM module 128. The cleaning tank 125 comprises an inner volume 125a defined by a top surface 125b and an outer surface 125c wherein an SPM 135 is contained. The cleaning tank 125 can generally be made from any suitable material, that is not reactive, to be used with a mixture of sulfuric acid and peroxide.

The cleaning tank 125 may also comprise injectors or dispersion plates (not shown) at a bottom of the cleaning tank 125 to introduce a laminar flow of chemicals into the cleaning tank 125. The cleaning tank 125 has a stationary lid 127 located at the top surface 125b of the cleaning tank 125. The stationary lid 127 may be hinged and may be opened for maintenance of the cleaning tank 125, but remains stationary during SPM cleaning of substrates. Preferably, the stationary lid 127 covers a majority of the top surface 125b of the cleaning tank 125. The cleaning tank 125 also has an input lid assembly 150a at an entry point in the cleaning tank 125, and an output lid assembly 150b at an exit point in the cleaning tank 125. The input lid assembly 150a and the output lid assembly 150b are disposed on opposing sides of the stationary lid 127. The input lid assembly 150a and the output lid assembly 150b each exposes a portion of an upper end of the cleaning tank 125, and may be actuated independently by the controller 160 (FIGS. 1A/1B). The input lid assembly 150a and the output lid assembly 150b may be hingedly actuated, retractably actuated, or removably actuated by the controller 160. The area of each of the input lid assembly 150a and the output lid assembly 150b is minimized such that, when opened, a minimal area of an inner volume of the cleaning tank 125 is exposed.

Depicted on the left of the cleaning tank 125 is an input tank 180 where a first wet robot 139a, controlled by the controller 160, places a substrate 10a to be cleaned into a substrate carrier 210. A first carrier transfer robot arm 137a, controlled by the controller 160, then grasps the substrate carrier 210 containing the substrate 10a and removes it from the input tank 180.

The controller 160 actuates the input lid assembly 150a to an open position. For example, the input lid assembly 150a may be hinged and opened via an actuator such as a motor, slidingly retracted via an actuator such as a motor or cylinder, or lifted via an actuator such as a robot arm. The first carrier transfer robot arm 137a then places the substrate carrier 210 through the opened input lid assembly 150a, submerging the substrate carrier 210 into the SPM 135 disposed in the cleaning tank 125 and onto a transport system, i.e., conveyor system 220. The conveyor system 220 is located on an upper portion 225a of the outer surface 125b of the cleaning tank 125. The first carrier transfer robot arm 137a retracts out of the cleaning tank 125, and the input lid assembly 150a closes, sealing the cleaning tank 125.

The conveyor system 220 may include a pair of continuous conveyor belts or linkages on a single or opposing sides of the cleaning tank 125 whose operating length spans the length of the cleaning tank 125. The continuous belts may each be a plurality of separate belts, such as three, whose total operating length spans the length of the cleaning tank 125. The substrate carrier 210 is placed onto an upper surface of each belt 219. Each belt 219 is actuated, for example by a motor, such that the substrate carrier 210 moves along the length of the belt 219 at a desired speed. The conveyor system 220 is controlled by the controller 160 to operate in sync to transport the substrate carrier 210 across the length of the cleaning tank 125 to a predetermined position under the output lid assembly 150b. The conveyor system 220 is actuated in such a manner as to cause a first isolation gap 230a from when the substrate carrier 210 is initially placed into the cleaning tank 125 and other substrate carriers already being processed within the cleaning tank 125. The first isolation gap 230a may be created by an initial pause at the beginning of the conveyor system 220 and then an increase in speed to match a predetermined gap 232 between other substrate carriers. Preferably, the substrate carrier 210 reaches the predetermined gap 232 while under the stationary lid 127. The conveyor system 220 may comprise multiple belts, such as three, where each belt has its own speed control. Alternatively, the conveyor system 220 may be disposed on an upper portion of the tank body 225a, a lower portion of the tank body 225b, or a combination thereof. The substrate carrier 210 then follows a motion path 240, via the conveyor system 220 while being processed. Before reaching the output lid assembly 150b, the conveyor system 220 is actuated to create a second isolation gap 230b in a similar manner to which the conveyor system 220 created the first isolation gap 230a. The output lid assembly 150b is actuated by the controller 160 into an open position similar to the input lid assembly 150a. Once the substrate carrier 210 moves across the second isolation gap 230b, a second carrier transfer robot arm 137b, controlled by the controller 160, lifts the substrate carrier 210 out of the SPM 135 and out of the cleaning tank 125 through the opened output lid assembly 150b. Once the substrate carrier 210 is out of the cleaning tank 125, the output lid assembly 150b is actuated into a closed position by the controller 160 in a similar manner to the input lid assembly 150a, sealing the cleaning tank 125.

The second carrier transfer robot arm 137b, controlled by the controller 160, then places the substrate carrier 210 into the hot/cold rinse tank 126 for processing. The hot/cold rinse tank 126 may also be configured similarly to the cleaning tank 125 and include a separate conveyor system and lid assembly system. The hot/cold rinse tank 126 is equipped for hot rinsing of sulfuric residues without shocking the substrate after SPM cleaning plus a cold de-ionized water rinse to cool the substrate to room temperature. This rinsing also cleans residue from the substrate carrier 210. When the substrate has been processed through the hot/cold rinse tank 126, the second carrier transfer robot arm 137b transfers the substrate carrier 210 into an output tank 182. The cleaned substrate 10b is removed from the substrate carrier 210 and transferred out for further processing in the CMP system 100 by a second wet robot 139b controlled via the controller 160. The substrate carrier 210 is then transferred back to the input tank 180 to receive another substrate via the first and/or second carrier transfer robot arms 137a, 137b.

The system described in FIG. 2 allows substrates to be processed individually and in batches. The cleaning tank 125 may be configured to process multiple substrates in multiple substrate carriers 210 at once, i.e., in batches, of a desired quantity of substrates, such as about 50, about 30, or about 20, wherein each substrate is in its own substrate carrier 210. Processing substrates in a batch mode achieves benefits to efficiency and materials usage for a number of substrates. Performing the cleaning or rinsing on substrates individually allows each substrate to be processed for a time directed by the controller 160 in the SPM module 128, which can be longer than the time in other system modules, without impacting the overall throughput of the CMP system 100 and allowing single substrate processing in other portions of the CMP system 100.

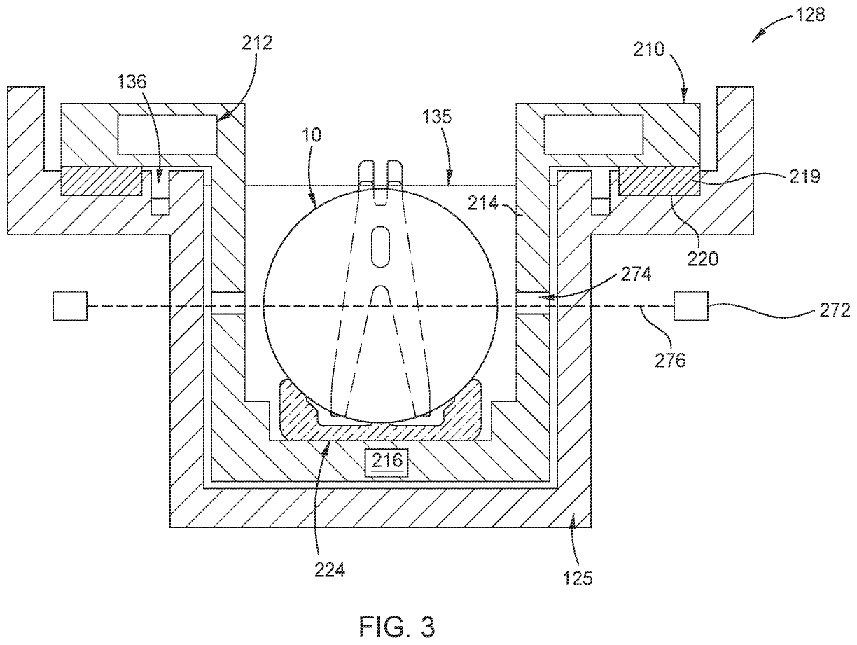

FIG. 3 illustrates a schematic front view of the cleaning tank 125 of the SPM module 128 including an exemplary embodiment of the described substrate carrier 210. The cleaning tank 125 has at least one overflow weir 136 that comprises a scalloped edge or V-shaped notches. The at least one overflow weir 136 allows overflowing SPM 135 to exit the cleaning tank 125 where the overflowing SPM 135 may be collected for disposal or recirculation.

As shown in FIG. 3, the substrate carrier 210 is disposed in the cleaning tank 125 and includes a carrier body 214. The carrier body 214 is sufficiently thin to allow a laminar flow of chemicals into the cleaning tank 125 from the injectors or dispersion plates (not shown) without disrupting the laminar flow. At least one lift handle feature 212 is incorporated in an upper portion of the carrier body 214 wherein the at least one lift handle feature 212 interacts with a lifting means, such as the carrier transfer robot arms 137a, 137b to lift the carrier body 214 into and out of the cleaning tank 125. A substrate holder 224 can be an incorporated feature within the carrier 210. The substrate holder 224 can project away orthogonally to allow for optional gripper robot end effectors when used to input the substrate 10 into the substrate carrier 210 or to remove the substrate 10 from the substrate carrier 210. The carrier body 214 may also comprise at least one component 274 of a presence sensor through beam system 272 configured to detect the location of the substrate carrier 210 within the cleaning tank 125 using a beam 276. The component 274 may be a window or an opening configured to allow a beam of the presence sensor system 272 to pass. At least one protrusion 216 extends from a bottom outer surface of the carrier body 214. The at least one protrusion 216 may be a single protrusion or a plurality of protrusions configured to maintain the predetermined gap 232 between sequential substrate carriers 210. The carrier body 214 is configured to interact with the conveyor system 220. For example, the at least one lift handle features 212 may contact at least one belt 219 of the conveyor system 220.

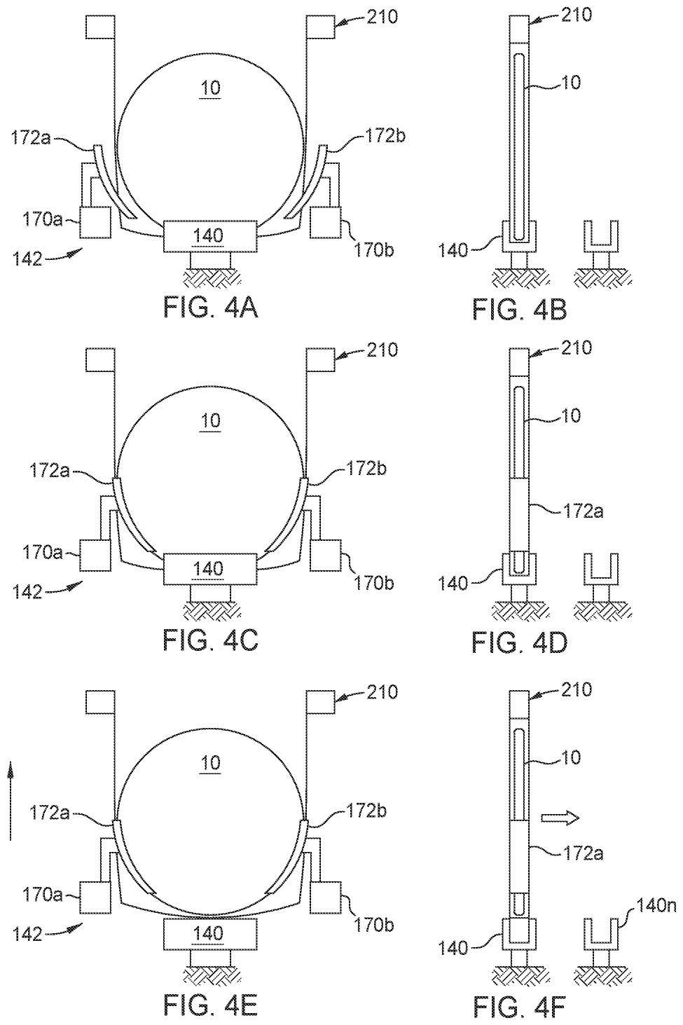

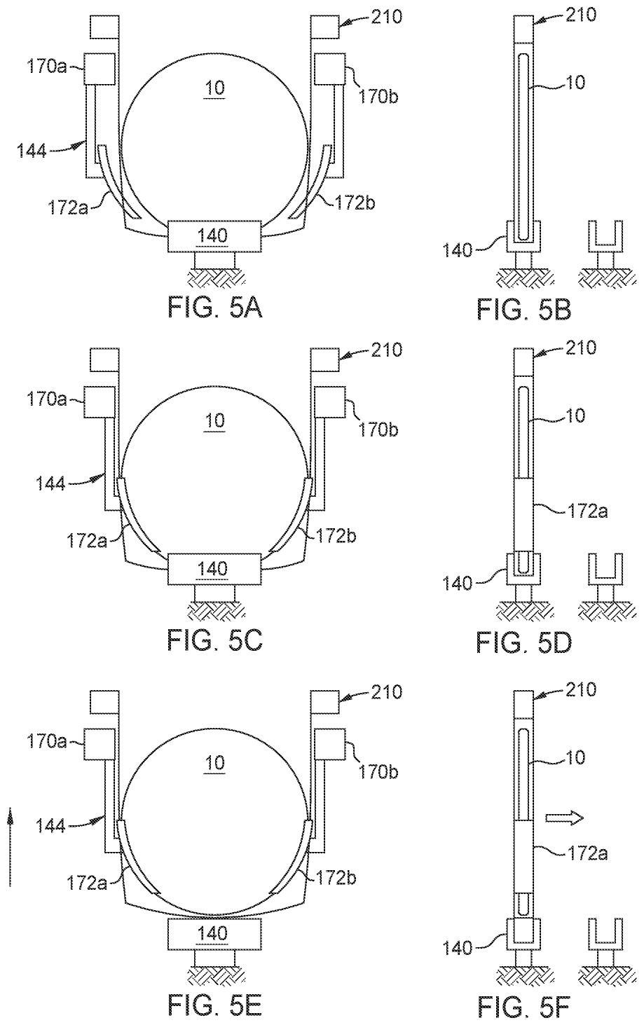

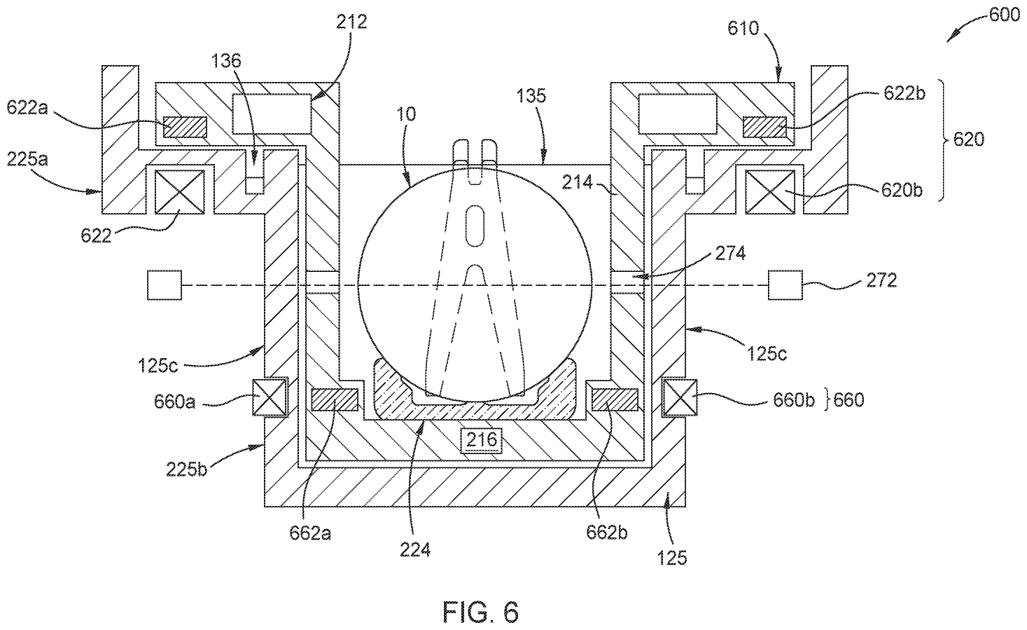

Alternative methods to the conveyor system described in FIG. 2 in which substrates are transported through the cleaning tank may use the various in-tank transport systems described herein, e.g., a walking beam system 142 of FIGS. 4A-4F, or a running beam system 144 of FIG. 5A-5F, or an electromagnetic coil levitation track system of FIG. 6, or another transport system.

FIGS. 4A-4F are schematic diagrams depicting the walking beam system 142 and the operation thereof. As shown in FIG. 4A, a substrate carrier 210 is positioned vertically in a support 140 within the cleaning tank 125 or the hot/cold rinse tank 126. FIG. 4B shows an edge view from the left of FIG. 4A of the substrate carrier 210 in the support 140. The walking beam is not shown for clarity. Referring again to FIG. 4A, adjacent the substrate carrier 210 on opposing sides are two walking beam rails 170a and 170b. Coupled to each walking beam rail, 170a and 170b, is a gripper, 172a and 172b, respectively. The grippers 172a, 172b can be arranged to be opposite one another and in line with the substrate carrier 210.

Upon a signal from the controller 160 (FIGS. 1A and 1B), as shown in FIG. 4C, the grippers 172a and 172b can be actuated to move toward the substrate carrier 210, thereby contacting the edges of the substrate carrier 210 on opposing sides of the substrate carrier 210. FIG. 4D shows the edge view of the substrate carrier 210 in the support 140 being contacted with the left gripper 172a.

As shown in FIG. 4E, the walking beam system 142 then raises the grippers 172a, 172b, thereby lifting the substrate carrier 210 from the support 140 to a height at which the bottom edge of the substrate carrier 210 is above the upper edge of the support 140. Alternatively, the support(s) 140 could be lowered so that the substrate is placed into the grippers 172a, 172b. The grippers 172a, 172b then move axially along the walking beams 170 to transfer the substrate carrier 210 to the next ordinal support 140n, as shown in FIG. 4F. When operating within the cleaning tank 125 and the hot/cold rinse tank 126, the grippers 172a, 172b operate in concert to transfer the substrate carriers 210 in the tanks simultaneously to the next ordinal support 140.

As another alternative, FIGS. 5A-5F depict details of a running beam system 144 which the cleaning tank 125 and the hot/cold rinse tank 126 of the SPM module 128 can use to control the movements of the substrate carriers 210. FIG. 5A depicts a running beam system 144 wherein the beams 170a, 170b extend longitudinally along the top of the tank. The grippers 172a, 172b extend downward from the beams 170a, 170b, aligning along opposite edges of the substrate carrier 210. FIG. 5B shows an edge view from the left of FIG. 5A of the substrate carrier 210 in the support 140. The running beam is not shown for clarity. Referring again to FIG. 5A, the running beam system 144 includes the same components as the walking beam 142 system, including beams 170a, 170b and grippers 172a, 172b.

Upon a signal from the controller 160 (FIGS. 1A and 1B), as shown in FIG. 5C, the grippers 172a and 172b can be actuated to move toward the substrate carrier 210 thereby contacting the edges of the substrate carrier 210 on opposing sides of the substrate carrier 210. FIG. 5D shows the edge view of the substrate carrier 210 in the support 140 being contacted with the left gripper 172a.

As shown in FIG. 5E, the grippers 172a, 172b retract upward after gripping the substrate carrier 210, thereby lifting the substrate carrier 210 from the support 140 to a height at which the bottom edge of the substrate carrier 210 is above the upper edge of the support 140. The grippers 172a, 172b then move axially along the running beams 170a, 170b to transfer the substrate carrier 210 to the next ordinal support, as shown in FIG. 5F. Whereas the walking beam system 142 moves the totality of substrate carriers 210 in a cleaning tank 125 or a hot/cold rinse tank 126 simultaneously, the running beam system 144 moves the substrate carriers 210 individually. The running beam system 144 moves the substrate carrier 210 nearest the exit of the cleaning tank 125 or the hot/cold rinse tank 126 to the next ordinal support 140, and works to move consecutive substrate carriers 210 toward the exit of the tank.

As yet another alternative, FIG. 6 depicts an electromagnetic (EM) coil levitation track system 600 which can be used to move the substrates 10 on substrate carriers 610 through the cleaning tank 125 (or the hot/cold rinse tank 126) of the SPM module 128. The substrate carriers 610 are similar to the substrate carriers 210 described above with additional features a described below. The EM coil levitation track system 600 may include an upper levitation track system 620 disposed on the upper portion 225a of the cleaning tank 125, a lower levitation track system 660 disposed on the lower portion 225b of the cleaning tank 125, or a combination thereof. The upper levitation track system 620 may include a first upper levitation track 620a, a second upper levitation track 620b, a first upper magnet 622a, and a second upper magnet 622b. The lower levitation track system 660 may include a first lower levitation track 660a, a second lower levitation track 660b, a first lower magnet 662a, and a second lower magnet 662b.

The upper magnets 622a, 622b may be any suitable superconductive magnet such as an aluminum nickel cobalt (AlNiCo) magnet. The upper magnets 622a, 622b are shown disposed or embedded within each lift handle feature 212 of the substrate carrier 610 but may also be disposed on a surface of the lift handle features. The upper magnets 622a, 622b are polarized such as to cause an opposing magnetic force against the upper levitation tracks 620a, 620b and lift the substrate carrier 610 upward. The upper levitation tracks 620a, 620b contain coils. The controller 160 (FIGS. 1A and 1B) induces an electric current within the coils of the upper levitation tracks 620a, 620b causing the coils to act as electromagnets temporarily. The like poles of the upper magnets 622a, 622b and the coil of upper levitation tracks 620a and 620b repel and push the substrate carrier 210 upward. Successive like poles on the upper levitation tracks 620a and 620b are successively energized by the controller 160 to push the substrate carrier 210 forward through the cleaning tank 125 (and/or hot/cold rinse tank 126).

Similarly, the lower magnets 662a, 662b may be any suitable superconductive magnet such as an AlNiCo magnet. The lower magnets 662a, 662b are shown disposed within opposing bottom corners of the substrate carrier 610, but may be disposed on any opposing surfaces of the substrate carrier 610. The lower magnets 662a, 662b are polarized such as to cause an opposing magnetic force against the lower levitation tracks 660a, 660b when the lower levitation tracks 660a, 660b are energized by the controller 160. Similar to the upper levitation tracks 620a, 620b, successive like poles on the lower levitation tracks 660a and 660b are successively energized by the controller 160 to push the substrate carrier 210 forward through the cleaning tank 125 (and/or the hot/cold rinse tank 126).

When introducing elements of the present disclosure or exemplary aspects or embodiment(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to embodiments of the present disclosure, other and further embodiments of the disclosure may be devised without departing from the basic scope thereof, and the scope thereof is determined by the claims that follow.

What is claimed is:

1. A system for cleaning a substrate, the system comprising:
an input tank;
a cleaning tank configured to contain a cleaning fluid for applying to the substrate, the cleaning tank comprising
a top surface and an outer surface adjacent to the top surface, the top surface and the outer surface defining an inner volume, the outer surface comprising:
an upper portion, and
a lower portion;
a transport system connected to the upper portion of the cleaning tank, the lower portion of the cleaning tank, or a combination thereof, the transport system configured to transport a substrate carrier containing the substrate;
a stationary lid covering a majority of the top surface of the cleaning tank;
at least one input lid assembly adjacent to a first side of the stationary lid; and
at least one output lid assembly adjacent to a second side of the stationary lid, wherein the at least one input lid assembly, the stationary lid, and the at least one output lid assembly cover an entirety of the top surface;
a rinse tank;
an output tank; and
a robot system comprising a plurality of robot arms configured to transfer the substrate carrier between the input tank, the cleaning tank, the rinse tank, and the output tank.

2. The system of claim 1, wherein the substrate carrier comprises:
a carrier body;
at least one lift handle feature incorporated in an upper portion of the carrier body; and
a substrate holder at a bottom inner surface of the carrier body configured to hold the substrate.

3. The system of claim 1, wherein the transport system is a conveyor system, a walking beam system, a running beam system, or an electromagnetic coil levitation track system.

4. The system of claim 1, wherein the transport system is a conveyor system comprising a plurality of belts or linkages on opposing sides of the cleaning tank, wherein the plurality of belts or linkages are actuated to cause a first isolation gap and a second isolation gap.

5. The system of claim 1, wherein the transport system is an electromagnetic coil levitation track system comprising an upper track system and a lower track system, wherein the upper track system and the lower track system each comprises a coil spanning a length of the cleaning tank, wherein the coil is configured to repel a magnet in the substrate carrier using an electromagnetic force when energized.

6. The system of claim 1, wherein the input lid assembly is configured to be actuated to allow a first portion of the top surface to be exposed such that the robot system transporting the substrate carrier may access the inner volume of the cleaning tank.

7. The system of claim 1, wherein the output lid assembly is configured to be actuated to allow a second portion of the top surface to be exposed such that the robot system may access the substrate carrier within the inner volume of the cleaning tank.

8. A substrate carrier comprising:
a carrier body;
at least one lift handle feature incorporated in an upper portion of the carrier body;
a substrate holder at a bottom inner surface of the carrier body configured to hold a substrate; and
a protrusion extending from an outer surface of the carrier body.

9. The substrate carrier of claim 8, further comprising at least one magnet.

10. The substrate carrier of claim 9, wherein the at least one magnet comprises a magnet embedded in each of two lift handle features of the at least one lift handle features.

11. The substrate carrier of claim 8, wherein the carrier body is configured to interact with at least one conveyor system.

12. A system for cleaning a substrate after chemical mechanical polishing, the system comprising:
an input tank;
a cleaning tank comprising a transport system;
a substrate carrier;
a rinse tank;
an output tank;
one or more wet robots;
a substrate carrier robot system; and
a controller configured to cause the system to:
insert a substrate into a substrate carrier in the input tank using the one or more wet robots;
transfer the substrate carrier from the input tank to the cleaning tank using the substrate carrier robot system;
transport the substrate in the substrate carrier through the cleaning tank for a predetermined period using the transport system;
remove the substrate carrier from the cleaning tank using the substrate carrier robot system;
insert the substrate carrier into the rinse tank using the substrate carrier robot system;
rinse the substrate in the substrate carrier in the rinse tank;
remove the substrate carrier from the rinse tank using the substrate carrier robot system;
place the substrate carrier into the output tank using the substrate carrier robot system; and
remove the substrate from the substrate carrier using the substrate carrier robot system.

13. The system of claim 12, wherein the substrate carrier comprises:
a carrier body;
at least one lift handle feature disposed on an upper portion of the carrier body; and
a substrate holder at a bottom inner surface of the carrier body configured to hold a substrate.

14. The system of claim 13, wherein substrate carrier further comprises one or more magnets.

15. The system of claim 12, wherein the cleaning tank comprises:
a top surface;
an outer surface adjacent to the top surface, the outer surface comprising:
an upper portion; and
a lower portion;
the transport system connected to the upper portion of the cleaning tank, the lower portion of the tank body, or a combination thereof;
a stationary lid covering a majority of a top surface of the cleaning tank;
at least one input lid assembly adjacent to a first side of the stationary lid; and
at least one output lid assembly adjacent to a second side of the stationary lid.

16. The system of claim 12, wherein the controller is further configured to cause the system to remove the substrate carrier from the output tank then placing the substrate carrier into the input tank for use with another substrate using the substrate carrier robot system.

17. The system of claim 12, wherein the transport system comprises a walking beam system.

18. The system of claim 12, wherein the transport system comprises a running beam system.

19. The system of claim 12, wherein the transport system comprises a conveyor system comprising a plurality of belts on opposing sides of the cleaning tank wherein the plurality of belts are actuated to cause a first isolation gap and a second isolation gap.

20. The system of claim 12, wherein the transport system comprises an electromagnetic coil levitation track system, the electromagnetic coil levitation track system comprising an upper track system and a lower track system, wherein the upper track system and the lower track system comprises a coil on opposing sides of the cleaning tank, wherein the coil is configured to repel a magnet in the substrate carrier using an electromagnetic force when energized by the controller.
